(19) United States
(12) Patent Application Publication
(10) Pub. No.: US 2002/0073539 A1
(43) Pub. Date: Jun. 20, 2002

(54) Method for manufacturing a spark plug

(76) Inventors: Tsunenobu Hori, Kariya-shi (JP); Kozo Takamura, Nagoya (JP)

Correspondence Address: NIXON & VANDERHYE P.C., 1100 North Glebe Rd., 8th Floor, Arlington, VA, 22201-4714, US

(21) Appl. No.: 10/011,305

(22) Filed: Dec. 11, 2001

(30) Foreign Application Priority Data
Dec. 15, 2000 (JP) 2000-382420
Sep. 25, 2001 (JP) 2001-291363

(51) Int. Cl. H05K 3/34; H01R 43/00

(52) U.S. Cl. 29/857; 29/840; 29/863

(57) ABSTRACT

A tip holding jig having a receiving hole is placed below an electrode of a spark plug. A noble metallic tip is positioned at least partly in an inlet of the receiving hole. The noble metallic tip is fixed to the electrode by resistance welding under a condition that the electrode presses the noble metallic tip to the jig.

### BACKGROUND OF THE INVENTION

The present invention relates to a method for manufacturing a spark plug having at least two opposed electrodes and a noble metallic tip fixed to an electrode surface of at least one of the opposed electrodes by resistance welding so as to form a discharge gap.

Unexamined Japanese patent publication No. 61-171080 discloses a conventional method for manufacturing a spark plug, according to which a noble metallic tip is lowered from above and placed on an electrode. To hold the noble metallic tip, a jig (i.e., chuck) is positioned higher than the electrode. The noble metallic tip is fixed to the electrode by resistance welding. This manufacturing method necessarily complicates the jig arrangement because the noble metallic tip needs to be held above the electrode.

Unexamined Japanese patent publication No. 51-87637 discloses another conventional method for manufacturing a spark plug, according to which one end of a noble metallic tip is inserted into a hole opened on the top of an electrode and the other end of the noble metallic tip is inserted into a hole of a power supply tool. The noble metallic tip is welded to the electrode under a pressed condition. This manufacturing method increases a thermal stress acting on the noble metallic tip because the side surface of the noble metallic tip is surrounded at least partly by the electrode. Furthermore, the manufacturing method requires a punching operation for providing the hole on the electrode and a cutting or swaging operation for removing a welding swell formed on a side surface of the electrode after finishing the welding operation. Accordingly, the production cost increases. The noble metallic tip is required to be relatively long. This increases the cost of the noble metallic tip.

### SUMMARY OF THE INVENTION

In view of the above-described problems, the present invention has an object to provide a spark plug manufacturing method which is capable of simplify thejig arrangement for the resistance welding, capable of preventing the noble metallic tip from dropping, and capable of performing the resistance welding properly.

Another object of the present invention is to reduce a thermal stress acting on a noble metallic tip and reduce the production cost of a spark.

In order to accomplish the above and other related objects, the present invention provides a first method for manufacturing a spark plug having at least two opposed electrodes and a noble metallic tip fixed to an electrode surface of at least one of the opposed electrodes by resistance welding so as to form a discharge gap. The first manufacturing method comprises a step of substantially flattening the electrode surface before the noble metallic tip is welded to the electrode surface, a step of preparing a jig for mounting the noble metallic tip thereon, a step of placing the flattened electrode surface on the noble metallic tip mounted on the jig, and a step of performing the resistance welding to fix the noble metallic tip to at least one of the electrodes.

According to the first manufacturing method, the noble metallic tip is stationarily held on the jig without requiring a complicated jig arrangement. Thus, the resistance welding for fixing the tip to the electrode is performed by using a simplified jig arrangement.

In performing the resistance welding by mounting the electrode on the noble metallic tip, it is possible to position the electrode right above or obliquely above the noble metallic tip.

Furthermore, according to the first manufacturing method, the noble metallic tip is welded onto a flattened surface of the electrode. This effectively reduces a thermal stress acting on the noble metallic tip because the side surface of the noble metallic tip is not surrounded by the electrode.

The first manufacturing method requires no punching operation applied to the electrode and no cutting or swaging operation succeeding the welding operation. This greatly reduces the production cost. The required size of the noble metallic tip is short. The cost for the noble metallic tip can be reduced.

The present invention provides a second method for manufacturing a spark plug having at least two opposed electrodes and a noble metallic tip fixed to an electrode surface of at least one of the opposed electrodes by resistance welding so as to form a discharge gap. The second manufacturing method comprises a step of substantially flattening the electrode surface before the noble metallic tip is welded to the electrode surface, a step of preparing a tip holding jig having a predetermined receiving hole in such a manner that the tip holding jig is located under said electrode, a step of positioning the noble metallic tip at least partly in an inlet of the receiving hole of the tip holding jig, and a step of performing the resistance welding to fix the noble metallic tip to at least one of the electrodes.

According to the second manufacturing method, the noble metallic tip is positioned below the electrode and placed stationarily on the jig due to gravity of the noble metallic tip. At least part of the noble metallic tip is held in the inlet of the receiving hole of the tip holding jig. Hence, the noble metallic tip can be stationarily held in the receiving hole. The second manufacturing method requires no special jig for securely holding the tip.

Accordingly, the present invention simplifies the jig arrangement for holding the noble metallic tip during the resistance welding and makes it possible to perform the resistance welding properly.

In performing the resistance welding, the jig can be positioned right below, obliquely below, or horizontally next to the electrode.

Furthermore, according to the second manufacturing method, the noble metallic tip is welded onto a flattened surface of the electrode. This effectively reduces a thermal stress acting on the noble metallic tip because the side surface of the noble metallic tip is not surrounded by the electrode.

The second manufacturing method requires no punching operation applied to the electrode and no cutting or swaging operation succeeding the welding operation. This greatly reduces the production cost. The required size of the noble metallic tip is short. The cost for the noble metallic tip can be reduced.

According to a preferable embodiment of the present invention, it is preferable that the noble metallic tip has a right rod body with a circular cross section, and the shape of the receiving hole is a cylindrical bore corresponding to the shape of the noble metallic tip, and the noble metallic tip is inserted from its axial end into the receiving hole.

Furthermore, it is preferable that the noble metallic tip is deformed into a shape corresponding to the receiving hole by applying a pressing force to the metallic tip received in the receiving hole during the resistance welding.

### BRIEF DESCRIPTION OF THE DRAWINGS

The above and other objects, features and advantages of the present invention will become more apparent from the following detailed description which is to be read in conjunction with the accompanying drawings, in which:

FIG. 1 is a cross-sectional view showing an essential arrangement of a spark plug in accordance with a preferred embodiment of the present invention;

FIGS. 2A and 2B are views explaining a resistance welding process for fixing a noble metallic tip to a ground electrode in accordance with a spark plug manufacturing method of the present invention;

FIGS. 3A to 3D are views explaining a resistance welding process for fixing a noble metallic tip to a center electrode in accordance with a spark plug manufacturing method of the present invention;

FIGS. 4A and 4B are views explaining another spark plug manufacturing method of the present invention;

FIG. 5 is a view explaining a modified step of fixing the noble metallic tip to the ground electrode in accordance with the spark plug manufacturing method of the present invention;

FIGS. 6A and 6B are views explaining modified examples of the positional relationship between a tip holding jig and an electrode in accordance with the present invention;

FIGS. 7A to 7C are views explaining a resistance welding process for fixing a noble metallic tip to a ground electrode in accordance with a modified spark plug manufacturing method of the present invention;

FIGS. 8A and 8B are cross-sectional views showing modified arrangements of the ground electrode tip in accordance with the preferred embodiment of the present invention; and

FIG. 9 is a view explaining a process for fixing a noble metallic tip to a ground electrode in accordance with a conventional spark plug manufacturing method.

### DESCRIPTION OF THE PREFERRED EMBODIMENTS

Preferred embodiments of the present invention will be explained hereinafter with reference to attached drawings. Identical or corresponding parts are denoted by the same reference numerals throughout the drawings.

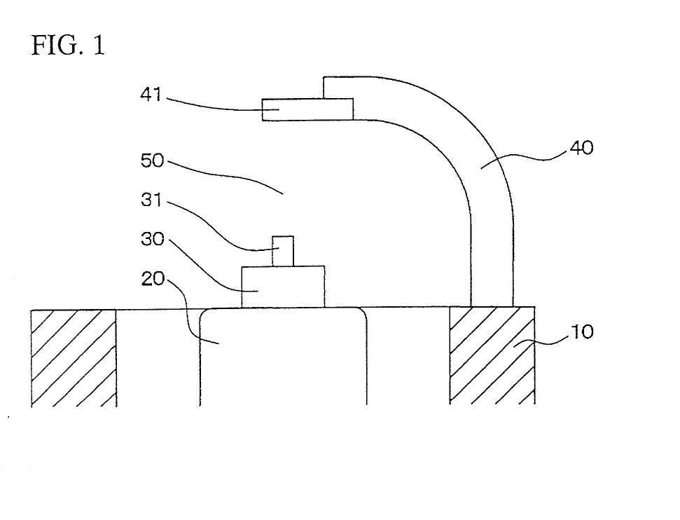

FIG. 1 shows an essential arrangement of a spark plug in accordance with a preferred embodiment of the present invention. As shown in FIG. 1, the spark plug of this embodiment has a metallic housing 10 which is made of a carbon steel and configured into a cylindrical shape, for example, through cold forging or cutting operations.

The metallic housing 10 has an inside space for accommodating a center electrode 30 made of a nickel alloy or comparable material via an insulator 20 made of an alumina or other electrical insulating material. In other words, the center electrode 30 is electrically insulated from the metallic housing 10. According to this embodiment, the center electrode 30 has a rodlike body extending in an axial direction of the plug, i.e., an up-and-down direction in FIG. 1. An apical end of center electrode 30 protrudes out of an axial end of metallic housing 10.

A center electrode tip 31, made of an iridium alloy, a platinum alloy, or a comparable noble metal, is fixed to the apical end (i.e., top) of center electrode 30 by resistance welding. The center electrode tip 31 can be configured into a cylindrical, or plate-like or any other shape. According to the embodiment shown in FIG. 1, the center electrode tip 31 has a columnar or cylindrical body with a diameter in a range from 0.5 mm to 0.7 mm and an axial length in a range from 0.6 mm to 0.8 mm. The center electrode 30 has an electrode surface onto which the center electrode tip 31 is welded. The electrode surface of center electrode 30 is substantially flattened before the center electrode tip 31 is welded to this electrode surface.

A ground electrode 40, made of a nickel alloy or comparable material, has a proximal portion fixed to the metallic housing 10 by welding. The proximal portion extends in parallel with the axial direction of the plug. The ground electrode 40 is curved at an intermediate portion thereof where the proximal portion ends. The ground electrode 40, curved approximately 90° at this intermediate portion, has a distal portion extending in a cantilever fashion from the intermediate portion in a direction normal to the axial direction of the plug. The distal portion is opposed to the center electrode tip 31.

A ground electrode tip 41, made of an iridium alloy, a platinum alloy or a comparable noble metal, is fixed to an apical end of the distal portion of ground electrode 40 by resistance welding. The ground electrode tip 41 can be configured into a cylindrical, or plate-like or any other shape. According to the embodiment shown in FIG. 1, the ground electrode tip 41 has a columnar or cylindrical body similar to the center electrode tip 31. The ground electrode 40 has an electrode surface onto which the ground electrode tip 41 is welded. The electrode surface of ground electrode 40 is substantially flattened before the ground electrode tip 41 is welded to this electrode surface.

In this manner, the spark plug shown in FIG. 1 has two opposed center and ground electrodes 30 and 40. And, the noble metallic tips 31 and 41 are fixed to apical surfaces of respective center and ground electrodes 30 and 40 by resistance welding so as to form a discharge gap 50.

More specifically, the discharge gap 50 is a clearance formed between the noble metallic tips 31 and 41. When a predetermined voltage is applied between the electrodes 30 and 40, a spark discharge occurs between the noble metallic tips 31 and 41.

The above-described spark plug of this embodiment is manufactured according to the following manufacturing method. The manufacturing method of this embodiment is characterized by the resistance welding process for fixing the noble metallic tips 31 and 41 to the electrodes 30 and 40. The rest of the manufacturing method of this embodiment is substantially identical with the conventional method and therefore will not be explained hereinafter.

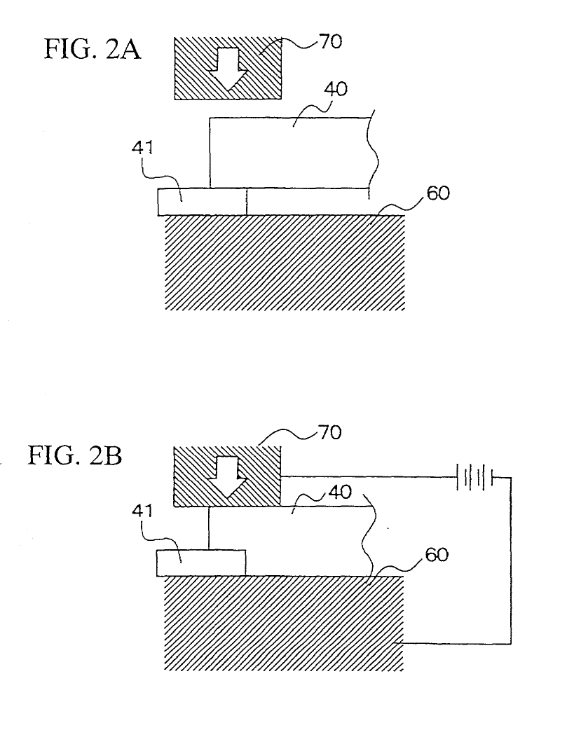

FIGS. 2A and 2B explain the resistance welding process for fixing the noble metallic tip 41 to the ground electrode 40.

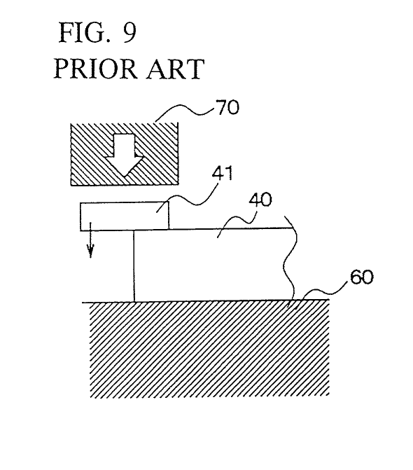

For the comparison with the manufacturing method of this embodiment, a conventional manufacturing method will be explained with reference to FIG. 9.

First, the ground electrode 40 is mounted on a base jig 60. Then, the noble metallic tip 41 is placed on an upper surface of the ground electrode 40. Then, both of the noble metallic tip 41 and the ground electrode 40 are pressed by an upper jig 70 toward the base jig 60. Then, the resistance welding is performed to weld or fix the noble metallic tip 41 to the ground electrode 40 under such a pressed condition. According to this conventional manufacturing method, to prevent the noble metallic tip 41 from dropping due to gravity, a special jig (i.e., chuck) is required to hold the noble metallic tip 41. This complicates the arrangement for the resistance welding.

On the other hand, the manufacturing method of this embodiment is simple. First, as shown in FIG. 2A, the noble metallic tip 41 is mounted on the base jig 60. Then, the ground electrode 40 is placed on an upper surface of the noble metallic tip 41 mounted on the base jig 60. Then, as shown in FIG. 2B, both of the noble metallic tip 41 and the ground electrode 40 are pressed by the upper jig 70 toward the base jig 60. Then, the resistance welding is performed to weld or fix the noble metallic tip 41 to the ground electrode 40 under such a pressed condition.

According to the manufacturing method of this embodiment, the resistance welding is performed properly without using a complicatedjig. Furthermore, the manufacturing method of this embodiment prevents the noble metallic tip 41 from dropping due to gravity. Thus, the resistance welding is performed stationarily. Although the disclosed embodiment shows an example using the upper jig 70 for pressing the noble metallic tip 41, it is also possible to push the base jig 60 upward while stationarily holding the upper jig 70.

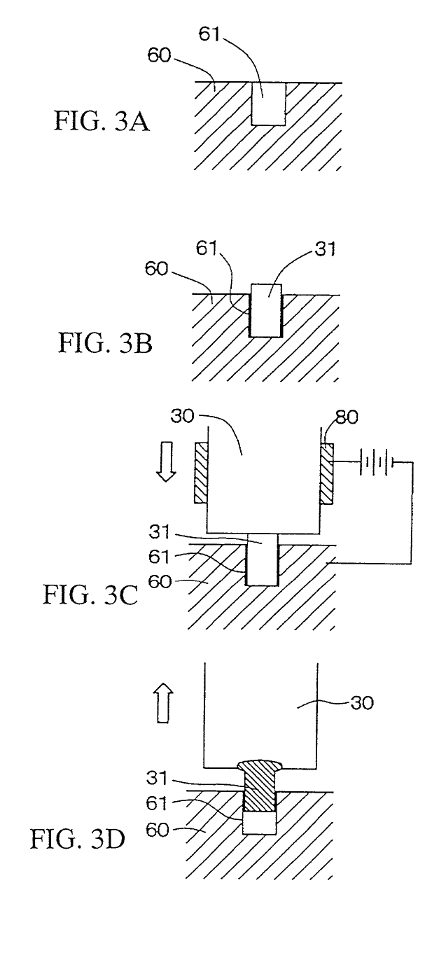

Next, a resistance welding process for fixing the noble metallic tip 31 to the center electrode 30 will be explained with reference to the illustrations shown in FIGS. 3A to 3D.

As shown in FIG. 3A, a tip holdingjig 60 having a predetermined receiving hole 61 is prepared. The tip holding jig 60 is located below the center electrode 30 (this is referred to as jig preparing process), while the tip holding jig 60 is grounded.

According to this embodiment, the noble metallic tip 31 has a right rod body with a uniform circular cross section. The shape of receiving hole 61 is a cylindrical bore corresponding to the shape of noble metallic tip 31. For example, the receiving hole 61 has an inner diameter in a range from 0.5 mm to 0.7 mm and a depth of approximately 0.6 mm. The depth is determined considering a welding margin for the noble metallic tip 31.

Next, the noble metallic tip 31 is inserted into an inlet of the receiving hole 61 (this is referred to as tip positioning process). According to this embodiment, as shown in FIG. 3B, the right rodlike noble metallic tip 31 is inserted into the receiving hole 61 until the leading end (i.e., axial end) of tip 31 reaches the bottom of receiving hole 61. Thus, the noble metallic tip 31 is held in the receiving hole 61.

Next, as shown in FIG. 3C, the center electrode 30 clamped by a chuck 80 of a welding machine is lowered until the center electrode 30 is brought into contact with a trailing end of the noble metallic tip 31. The center electrode 30 presses the noble metallic tip 31 to the tip holding jig 60. Under such a pressed condition, the resistance welding is performed by supplying a predetermined current between the noble metallic tip 31 and the center electrode 30 (this is referred to as welding process).

Through the resistance welding, as shown in FIG. 3D, the trailing end of noble metallic tip 31 is deformed into a flange shape. Thus, the noble metallic tip 31 is firmly welded to the center electrode 30 with a widened connecting area at this flange portion. After finishing the welding operation, the noble metallic tip 31 is disengaged from the tip holding jig 60 by raising the center electrode 30 upward. Thus, the welding process for fixing the noble metallic tip 31 to the center electrode 30 is accomplished.

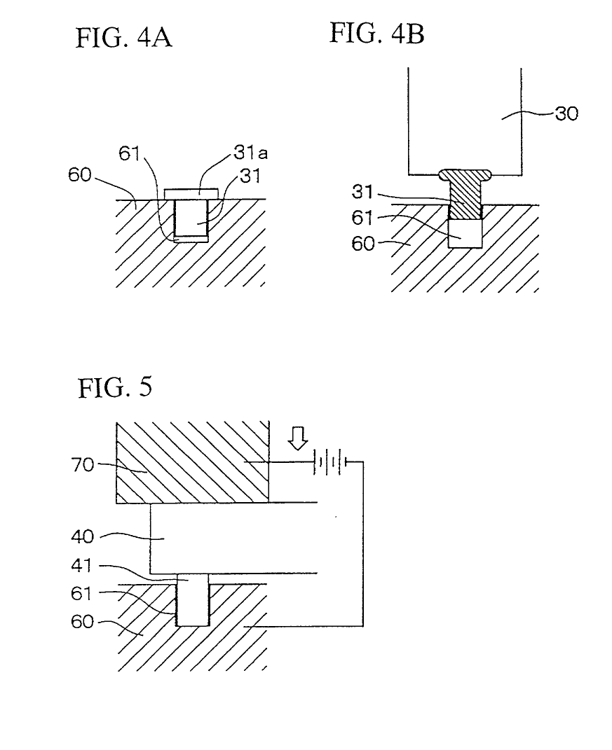

Instead of using the right rod body having an uniform diameter, it is possible to use a rivet-shaped noble metallic tip 31 having a flange portion 31a as shown in FIG. 4A. The flange portion 31a has a diameter larger than the inner diameter of the receiving hole 61. In this case, the flange portion 31a is brought into contact with the periphery of the inlet of receiving hole 61 so that the noble metallic tip 31 is held in the receiving hole 61.

Like the above-described noble metallic tip 31, after finishing the jig preparing process shown in FIG. 3A, the noble metallic tip 31 is inserted into the receiving hole 61 of the tip holding jig 60 as shown in FIG. 4A (this is referred to as tip positioning process). Then, like the process shown in FIG. 3C, the resistance welding operation is performed to weld the noble metallic tip 31 to the center electrode 30 as shown in FIG. 4B.

FIG. 5 shows a modified resistance welding process for fixing the noble metallic tip 41 to the ground electrode 40 which can be performed in the same manner as the above-described process for fixing the noble metallic tip 31 to center electrode 30.

First, like the steps shown in FIGS. 3A and 3B, the tip holding jig 60 is located below the ground electrode 40 (this is referred to as jig preparing process). Then, the noble metallic tip 41 is inserted from its axial end (i.e., leading end) into the receiving hole 61 of tip holding jig 60 so that the noble metallic tip 41 is held in the receiving hole 61 (this is referred to as tip positioning process).

Next, as shown in FIG. 5, the ground electrode 40 is brought into contact with the other end (i.e., trailing end) of noble metallic tip 41. The upper jig 70 presses the ground electrode 40 and the noble metallic tip 41 to the base jig 60. Under such a pressed condition, the resistance welding is performed by supplying a predetermined current between the noble metallic tip 41 and the ground electrode 40 (this is referred to as welding process). Through the resistance welding, the noble metallic tip 41 is firmly welded to the ground electrode 40. After finishing the welding operation, the noble metallic tip 41 is disengaged from the tip holding jig 60 by raising the ground electrode 40 upward. Thus, the welding process for fixing the noble metallic tip 41 to the center electrode 40 is accomplished.

As described above, according to the manufacturing method of this embodiment, the noble metallic tip is positioned at least partly in the inlet of the receiving hole of the tip holdingjig located below the electrode. Hence, the noble metallic tip can be stationarily held in the receiving hole due to the gravity of the tip. The manufacturing method of this embodiment requires no special jig for securely holding the tip.

It is needless to say that the electrode can be pressed upward from the direction of the base jig.

Furthermore, according to the manufacturing method of this embodiment, the resistance welding is performed under the condition that the electrode (30, 40) is pressed from above toward the tip (31, 41) mounted on the base jig (60). Thus, the manufacturing method of this embodiment simplifies the jig arrangement required for holding the noble metallic tip (31, 41) during the resistance welding operation.

Furthermore, according to the manufacturing method of this embodiment, the noble metallic tip (31, 41) is welded onto a flattened surface of the electrode (30, 40). This effectively reduces a thermal stress acting on the noble metallic tip (31, 41) because the side surface of the noble metallic tip (31, 41) is not surrounded by the electrode (30, 40). The manufacturing method of this embodiment requires no punching operation applied to the electrode and no cutting or swaging operation succeeding the welding operation. This greatly reduces the production cost. The required size of the noble metallic tip (31, 41) is short. The cost for the noble metallic tip (31, 41) can be reduced.

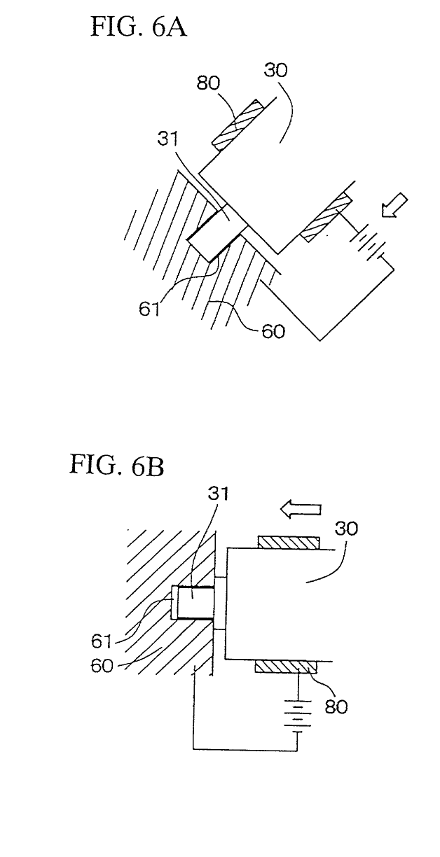

FIGS. 6A and 6B show modified examples of the positional relationship between the tip holding jig 60 and the center electrode 30. Although not shown in the drawing, these positional relationships can be applied to the relationship between the tip holding jig 60 and the ground electrode 40.

According to the positional relationship shown in FIG. 6A, the position of tip holding jig 60 is obliquely below the center electrode 30. According to the positional relationship shown in FIG. 6B, the tip holding jig 60 is horizontally next to the center electrode 30. In each case, the noble metallic tip is stationarily held in the receiving hole 61 due to gravity of noble metallic tip.

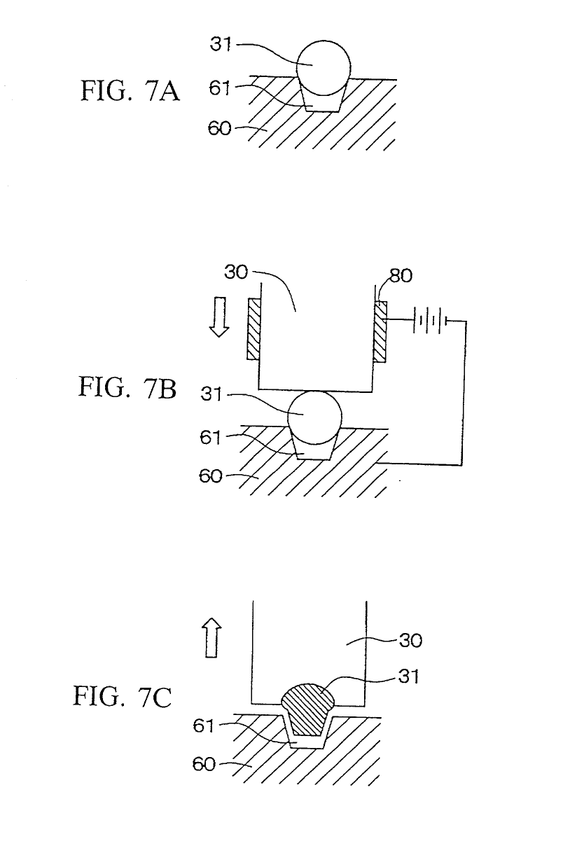

FIGS. 7A to 7C show a modified manufacturing method of this embodiment, which is characterized in that the noble metallic tip is deformed into a desired shape during the welding operation.

For example, as shown in FIG. 7A, the noble metallic tip 31 has a spherical shape. The noble metallic tip 31 is positioned at least partly in the inlet of receiving hole 61 as shown in FIG. 7A. Then, the center electrode 30 is lowered to deform the noble metallic tip 31 into a shape corresponding to the receiving hole 61, while the resistance welding is performed by supplying a predetermined current between the noble metallic tip 31 and the center electrode 30 as shown in FIG. 7B. This manufacturing method is advantageous in that the noble metallic tip can be easily configured into a desirable shape, e.g., a rod shape, a truncated conical shape, or the like.

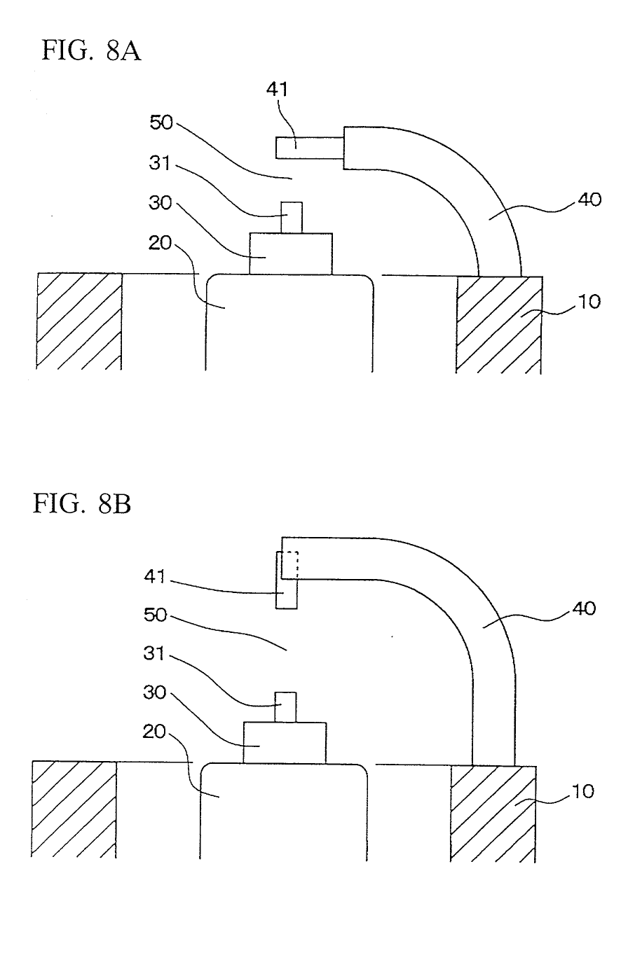

FIGS. 8A and 8B show modified arrangements of ground electrode tip 41. According to the arrangement shown in FIG. 8A, the noble metallic tip 41 is fixed to an apical surface of the ground electrode 40 and extends in a radial direction of the plug. According to the arrangement shown in FIG. 8B, the noble metallic tip 41 is fixed to the apical surface of the ground electrode 40 and extends in an axial direction of the plug. In each case, the discharge gap 50 is formed between the noble metallic tip 41 of ground electrode 40 and the noble metallic tip 31 of center electrode 30. The noble metallic tip can be welded to the electrode according to the resistance welding method explained with reference to FIGS. 2, 3, or 7.

The present invention can be applied to a spark plug having only one noble metallic tip fixed to either the center electrode or the ground electrode.

Furthermore, the present invention can be applied to a spark plug having two or more ground electrodes opposed to a common center electrode.

This invention may be embodied in several forms without departing from the spirit of essential characteristics thereof. The present embodiments as described are therefore intended to be only illustrative and not restrictive, since the scope of the invention is defined by the appended claims rather than by the description preceding them. All changes that fall within the metes and bounds of the claims, or equivalents of such metes and bounds, are therefore intended to be embraced by the claims.

What is claimed is:

1. A method for manufacturing a spark plug having at least two opposed electrodes and a noble metallic tip fixed to an electrode surface of at least one of said opposed electrodes by resistance welding so as to form a discharge gap, said method comprising the steps of:
substantially flattening said electrode surface before said noble metallic tip is welded to said electrode surface;
preparing a jig for mounting said noble metallic tip thereon;
placing said flattened electrode surface on said noble metallic tip mounted on said jig; and
performing the resistance welding to fix said noble metallic tip to said at least one of said electrodes.

2. A method for manufacturing a spark plug having at least two opposed electrodes and a noble metallic tip fixed to an electrode surface of at least one of said opposed electrodes by resistance welding so as to form a discharge gap, said method comprising the steps of:
substantially flattening said electrode surface before said noble metallic tip is welded to said electrode surface;
preparing a tip holding jig having a predetermined receiving hole in such a manner that said tip holding jig is located under said electrode;
positioning said noble metallic tip at least partly in an inlet of said receiving hole of said tip holding jig; and
performing the resistance welding to fix said noble metallic tip to said at least one of said electrodes.

3. The method for manufacturing a spark plug in accordance with claim 2, wherein
said noble metallic tip has a right rod body with a circular cross section, and the shape of said receiving hole is a cylindrical bore corresponding to the shape of said noble metallic tip, and
said noble metallic tip is inserted from its axial end into said receiving hole.

4. The method for manufacturing a spark plug in accordance with claim 2, wherein
said noble metallic tip is deformed into a shape corresponding to said receiving hole by applying a pressing force to said metallic tip received in said receiving hole during the resistance welding.
